(19) United States
(12) Patent Application Publication
(10) Pub. No.: US 2005/0207098 A1
(43) Pub. Date: Sep. 22, 2005

(54) Electrical equipment housings having a horizontally mounted connection plane

(76) Inventor: Christopher G. Malone, Loomis, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/801,791

(22) Filed: Mar. 16, 2004

(51) Int. Cl. H05K 5/00

(52) U.S. Cl. 361/679

(57) ABSTRACT

There is described a housing for mounting electronic boards therein, the housing having at least one horizontally positioned plane, adapted for allowing a plurality of electronic circuits to be connected thereto. The plane is arranged to allow air to flow between opposing walls of the housing without causing the air to traverse bends. The electronic circuits may be positioned on both the top and bottom surface of the horizontal plane. In one embodiment, the housing is a computer.

### DESCRIPTION OF RELATED ART

It has become common to arrange electrical equipment housings, such as computers and the like, with a back-plane having thereon a plurality of connectors. These connectors are adapted for mating with electrical equipment, such as PC boards, which in turn are used to control the equipment. When the system is in operation, the electrical components generate heat that must be removed in order to prevent system failures. The ability to remove heat is a gating factor as to the number of electrical components that can be positioned within a given size of housing.

It has also become common to force air through electrical equipment housings to remove heat from the equipment. Increasing air flow is a major factor in increasing heat removal. However, there is a practical limit to the air flow capacity of a given housing. Because the back-plane upon which the equipment is mounted is positioned in the air flow path, the back-plane itself impedes air flow through the housing.

### BRIEF SUMMARY OF THE INVENTION

In one embodiment, there is described a housing for mounting electronic boards therein, the housing having at least one horizontally positioned plane, adapted for allowing a plurality of electronic circuits to be connected thereto. The plane is arranged to allow air to flow between opposing walls of the housing without causing the air to traverse bends. The electronic circuits may be positioned on both the top and bottom surface of the horizontal plane. In one embodiment, the housing is a computer.

### BRIEF DESCRIPTION OF THE DRAWINGS

FIG. 1 shows a perspective view of one embodiment of an electrical equipment housing;

FIG. 2 shows a side sectional view of the housing taken along line 1B-1B of FIG. 1;

FIG. 3 is one embodiment of an electronic board;

FIG. 4 shows a side view of the housing of FIG. 1 just prior to the insertion of a first electronic board; and

FIG. 5 shows one embodiment of multiple electronic boards inserted on the top and bottom surfaces of a horizontally positioned mounting surface.

### DETAILED DESCRIPTION

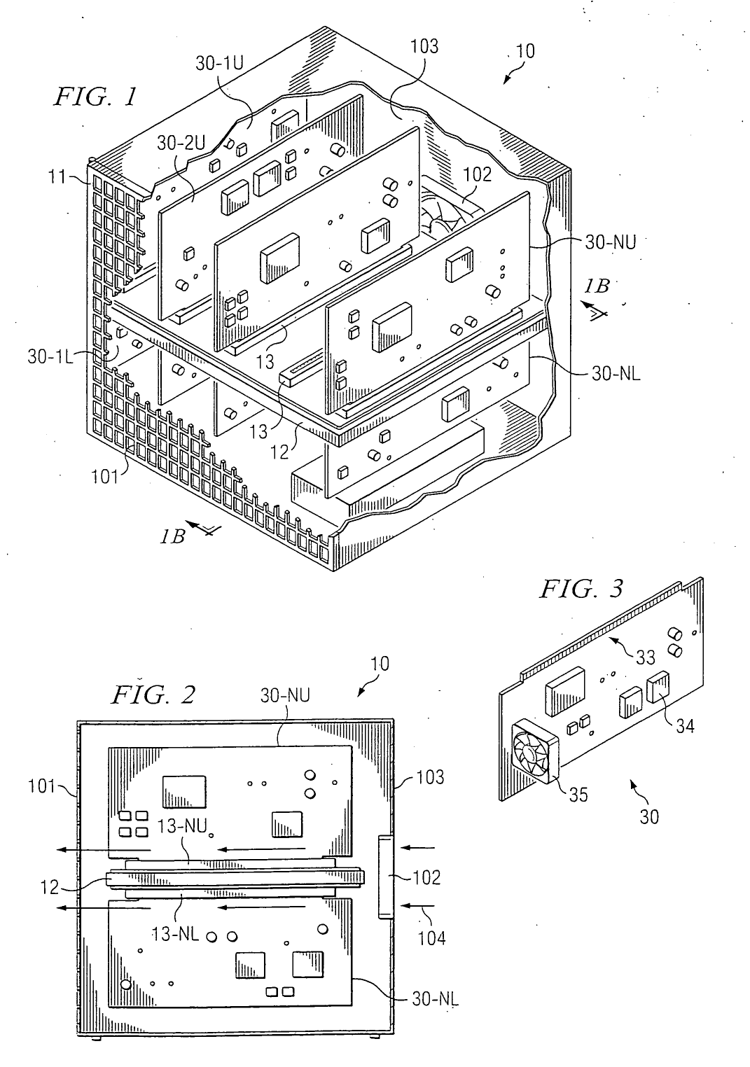

FIG. 1 shows one embodiment of housing 10 in which electrical components, such as electronic boards 30 are positioned. Housing 10 has front vertical surface 101 having contained therein, if desired, an opening for the insertion of the electronic boards, such as electronic boards 30-1U to 30-NL. In the embodiment shown, horizontal mounting structure 12 has mounted thereon connectors 13 adapted for receiving contacts 33 (shown in FIG. 3) of the electronic boards. In FIG. 1, the electronics boards are plug-in circuit boards of a computer.

In the embodiment shown, mounting structure 12 (which is the mounting plane for the plug-in boards) has connectors 13 mounted on both its top and bottom surfaces. Note that in other embodiments the connectors may be mounted only on one surface and, if desired, there may be multiple mounting structures (not shown) stacked within the housing. It is contemplated that those surfaces would all be horizontal, but some could, if desired, be vertical. As will be discussed, air can flow between front vertical surface 101 and back vertical surface 103 such that the air traverses the area essentially parallel to mounting surface 12 and in-line with the electronic boards mounted to surface 12. As shown, the electronic boards are mounted perpendicular to mounting surface 12, but could be mounted at any angle thereto. While plug-in wiring boards are shown, any type of component could be attached to surface 12 using, for example, a pigtail electrical connection and a mechanical support.

One system that is particularly adaptable for the arrangements discussed here is a computer system wherein each plug-in board is a blade of the system, such blade typically contains all of the elements of a traditional computer, namely processors, memory, and I/O. The air flows along the plane of mounting surface 12 and in-line with the electronic boards, the air need not bend around either the mounting surface or the components mounted on the electronic boards. This moving air is free to impact components mounted on both sides of the mounted electronic boards and thus can carry heat away from both sides of the boards.

Fan 102, shown mounted in the back vertical surface opposite the front vertical surface, causes air to flow between the front and back vertical surfaces. The fan could be designed to blow air in or suck air out as desired. Also, as will be discussed, the fan (or a number of fans) could be mounted internally within housing 10 as well. Also, in some situations, the fan could be eliminated, allowing natural convection to carry heat away from the components.

As shown in FIG. 1, any number of plug-in boards 30 may be mounted on surface 12. In this embodiment, boards 30-1U to 30-NU are shown plugged into connectors on the top surface of structure 12 while boards 30-1L to 30-NL are shown plugged into connectors on the bottom (or underside) of surface 12.

FIG. 2 shows a side sectional view of housing 10 taken along section line 1B-1B of FIG. 1. Electronic board 30-NU is shown plugged into connector 13-NU mounted on the top surface of structure 12 and electronic board 30-NL is shown plugged into connector 13-NL mounted on the bottom surface of structure 12. Air 104, controlled in part by fan 102, is shown flowing from back vertical panel 103 and out front vertical panel 101. As can be seen, this air flows essentially parallel to structure 12 without traversing around bends. This air will flow easily past all of the electronic components mounted on both the top and, if desired, bottom surfaces of structure 12 without mechanical hindrance.

Electronic boards 30 may be inserted into the various connectors 13 for example, by opening a door (not shown) in the vertical panel or by removing the panel. The board to be inserted is first positioned over (or under) the desired connector and then pressed downward (or upward) for insertion into the connector. Once in place, friction (and/or locking mechanism) between the connector and the pins of the electronic board maintains the board in mating relationship. Alternatively, a bracket (not shown) can be used to hold the board and the connector together, if desired.

FIG. 3 shows one embodiment 30 of an electronic board having contacts 33 for mating with connector 13. Mounted on board 30 are components 34. Not shown are components mounted within or on the other side of board 30. Fan 35 is shown and maybe optionally mounted on one or more boards as desired. Fan 35 may be used in conjunction with, or as a substitute for, fan 102 (FIG. 1). The system could be designed such that each board (or each group of boards) contains its own fan so that as the system grows (i.e., more and more boards connected within housing 10), the air moving capability would also grow in direct proportion to the number of connected boards.

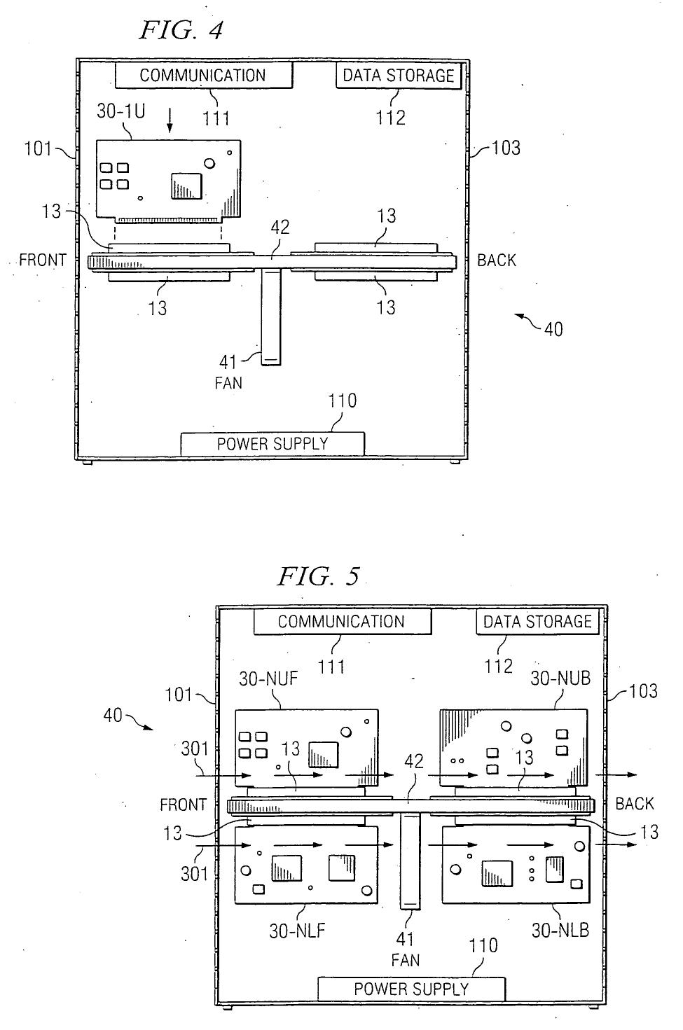

FIG. 4 shows a side view of housing 40 just before board 30-1U is inserted downward into connector 13 mounted on the top surface of horizontal structure 12. Board 30-1U is positioned over connector 13 by insertion through an opening in front vertical surface 101 as previously discussed. Mounting structure 42 is the same as structure 12 (plane 3) except that both the top and bottom surfaces of structure 42 contain dual rows of connectors for higher density. Also, structure 42 of housing 40 has fan 41 positioned thereon. Housing 40 is shown with communication devices 111, data storage devices 112 and power supply 110, one or more of which devices would typically be found within a computer. Other such devices can also be contained within the housing, if desired. In some cases, these devices could also be plugged into a connector positioned on structure 42.

FIG. 5 shows housing 40 having several plug-in boards mounted therein in dual upper and dual lower rows. Boards 30-NUF to 30-NUB are shown on the top surface of structure 12 while boards 30-NLF to 30 NLB are shown plugged upward onto the bottom surface. Fan 41 draws air 301 in through vents in front surface 101 and causes the air to flow past all of the boards plugged into connectors on the bottom surface of mounting structure 42. The air is forced out of vents in vertical back surface 103. Air flow on the top of surface 42 could be controlled in a similar fashion, or could be controlled by a fan in one or more of the vertical surfaces or by fans connected to one or more electrical boards 30. This then allows for dual airflow control.

While, in theory, the air could move in other directions (for example, air drawn in through the front and rear and forced out through the top and bottom) through housing 40, this is not practical because the housings are often mounted into a system with their respective sides in close proximity to each other.

1. A housing for mounting electronic equipment therein, said housing comprising:
at least one horizontally positioned mounting surface, said mounting surface positioned between a top and bottom of said housing and having provisions for accepting electrical components positioned thereon such that air may flow between opposing vertical walls of said housing flows along the plane of said mounting surface without traversing bends.

2. The housing of claim 1 wherein said electrical components comprise plug-in board connectors.

3. The housing of claim 2 wherein said plug-in connections are in-line with said air flow.

4. The housing of claim 1 further comprising:
at least one air fan mounted on a first one of said opposing vertical walls of said housing; and
at least one air vent constructed in a second one of said opposing vertical walls of said housing.

5. The housing of claim 1 further comprising:
a fan for moving air between said opposing vertical surfaces; and at least one air opening in each of said opposing vertical surface.

6. The housing of claim 5 wherein said fan is mounted on said horizontally positioned mounting surface.

7. The housing of claim 1 further comprising:
a plurality of electronic components connected to said mounting surface, said electronic components extending perpendicular to said mounting surface and in-line with said air moving between said opposing vertical surfaces.

8. The housing of claim 7 further comprising at least one fan mounted on at least one of said connected components.

9. The housing of claim 7 wherein said electronic components are plug-in boards.

10. The housing of claim 1 wherein said provisions for accepting electrical components are positioned on both the top and bottom surfaces of said horizontal mounting surface.

11. The housing of claim 10 wherein air flow above and below said horizontal mounting surface is controlled independently.

12. The housing of claim 1 wherein said mounting surface has positioned thereon a plurality of plug-in boards, said positioned boards being blades of a computer system.

13. The housing of claim 1 wherein further comprising:
a second horizontal mounting surface mounted parallel to send at least one mounting surface and positioned away from either said top or said bottom of said housing.

14. A computer comprising:
at least one mounting plane within said computer, each said mounting plane having mounted thereon a plurality of connectors, each connector adapted for mating with perpendicularly disposed plug-in boards such that air transiting from a first vertical wall of said computer to an opposing vertical wall of said computer flows parallel to said mounting plane and in-line with mated ones of said plug-in boards.

15. The computer of claim 14 wherein each said mounting plane is mounted parallel to the top and bottom of said computer.

16. The computer of claim 15 wherein said connectors are mounted on the top and bottom surfaces of at least one of said mounting planes.

17. The computer of claim 15 wherein at least one of said plug-in boards is a blade of a computer system.

18. The computer of claim 15 further comprising:
an opening in one of said vertical surfaces, said opening allowing plug-in boards to be mated with said connectors on either the top or bottom surface of at least one of said mounting planes.

19. The computer of claim 15 further comprising:
at least one fan operative for forcing air between a front vertical surface and a back vertical surface of said computer.

20. A method for mounting electrical components within a computer housing, said method comprising:
inserting a first one of said electrical component through an opening in a first vertical portion of said housing;
connecting said inserted electrical component to a structure such that connected ones of said electrical components is maintained at an angle to said structure, said structure having been horizontally pre-positioned within said housing; and
moving air between said first vertical portion of said housing and an opposing vertical portion of said housing along the plane of said structure.

21. The method of claim 20 wherein said connecting comprises:
mating said electrical component with said structure using plug-in connectors.

22. The method of claim 20 further comprising:
moving said air independently above or below said structure.

23. A system for reducing air flow restrictions in a housing, said system comprising:
means for capturing electrical components within said housing, said captured components each maintained at an angle to said capturing means; and
means for supporting a plurality of said capturing means, said supporting means positioned such that air flowing between vertical surfaces of said containing means moves without bending around said supporting means.
